(19) United States
(12) Patent Application Publication
(10) Pub. No.: US 2014/0060915 A1
(43) Pub. Date: Mar. 6, 2014

(54) SERVER CABINET

(71) Applicants: AN-GANG LIANG, Shenzhen City (CN); MING-YU LIU, Shenzhen City (CN)

(72) Inventors: AN-GANG LIANG, Shenzhen City (CN); MING-YU LIU, Shenzhen City (CN)

(21) Appl. No.: 13/627,991

(22) Filed: Sep. 26, 2012

(30) Foreign Application Priority Data
Aug. 29, 2012 (CN) 2012103120608

(51) Int. Cl. H05K 5/02

(52) U.S. Cl. 174/520

(57) ABSTRACT

A server cabinet includes a rack and a power distribution unit (PDU). The rack includes a top plate, a bottom plate, and a side plate connected between sides of the top plate and the bottom plate. A through hole is defined in the top plate, near a front end of the top plate. An opening is defined in the bottom plate, near a front end of the bottom plate. The PDU is fastened on an inner side of the side plate, near a front side of the rack. A power cable of the PDU is extendable out of the rack through the through hole or the opening.

### BACKGROUND

1. Technical Field

The present disclosure relates to a server cabinet.

2. Description of Related Art

In a data center, as the position of the power socket providing power for a power distribution unit (PDU) of a server cabinet varies, different structures are designed in different server cabinets. However, a structure of one type of server cabinets is usually only suitable for a situation when the power socket is located in one particular position, which leads to poor adaptability of the server cabinets.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a server cabinet.

FIG. 2 is an enlarged view of a circled portion II of FIG. 1.

FIG. 3 is an enlarged of a part of inverted view of FIG. 1.

FIG. 4 is an exploded, isometric view of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

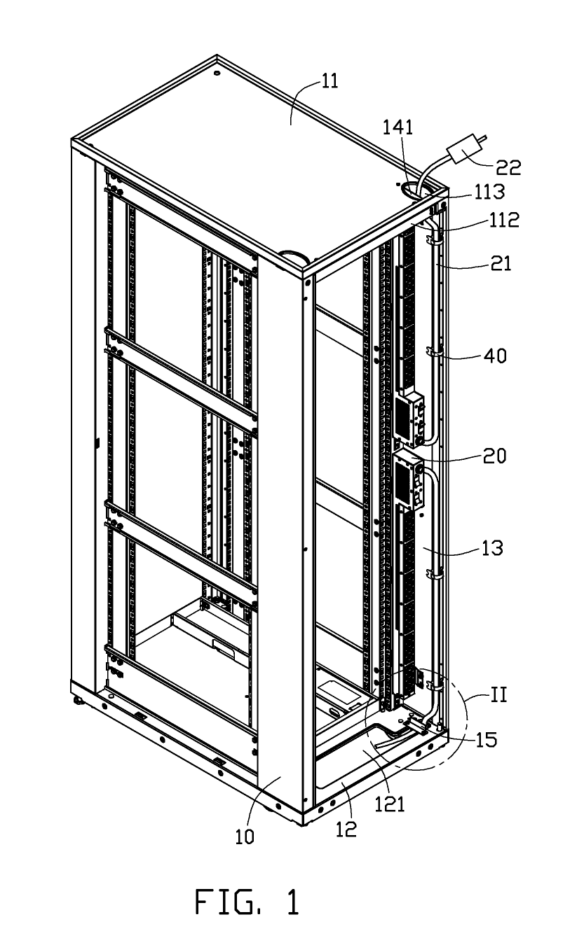

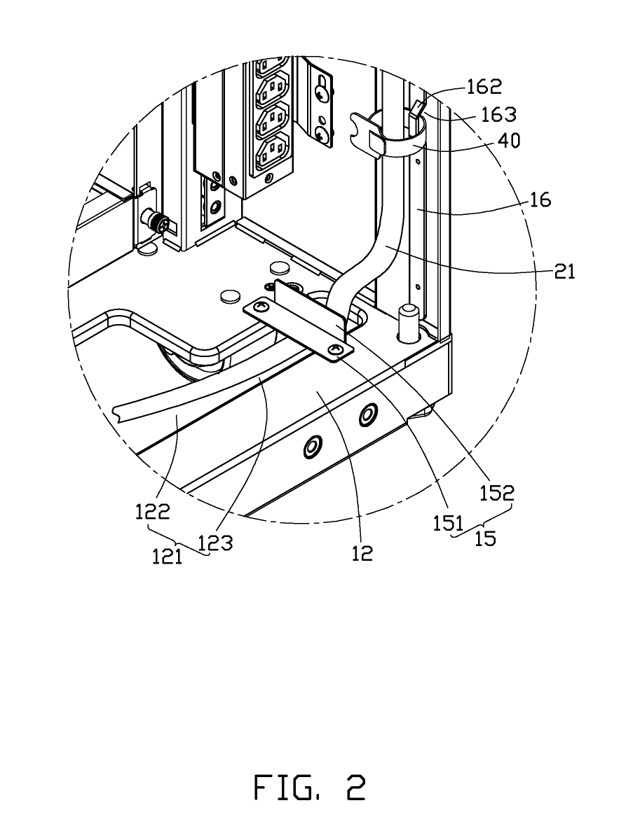

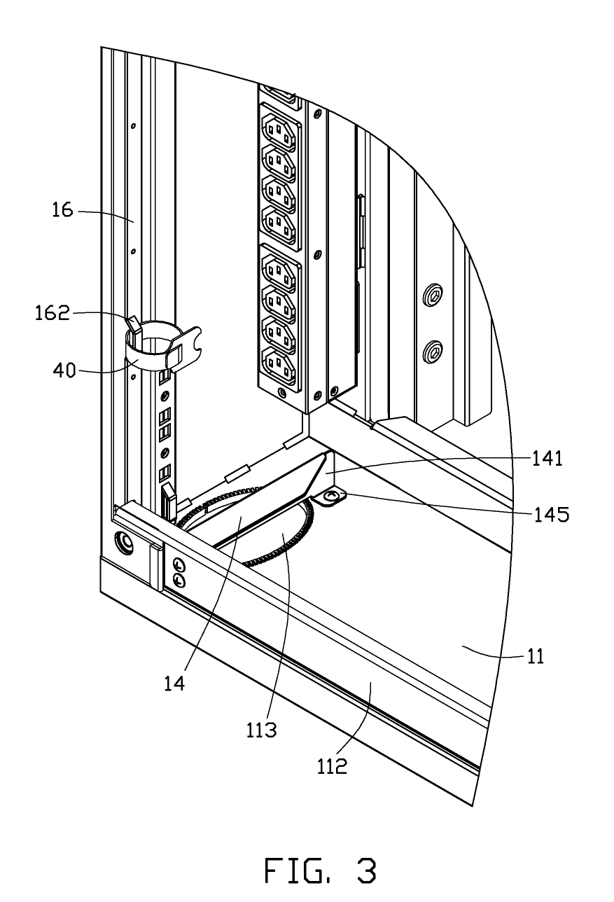

FIGS. 1 to 3 show an exemplary embodiment of a server cabinet including a rack 10 and two power distribution units (PDUs) 20.

The rack 10 includes a top plate 11, a bottom plate 12, a side plate 13 connected between sides of the top plate 11 and the bottom plate 12, a limitation member 14, and a stop member 15.

An extension plate 112 perpendicularly extends down from a front end of the top plate 11 toward the bottom plate 12. A through hole 113 is defined in the top plate 11, near the front end of the top plate 11. A pole 16 is fastened on an inner side of the side plate 13, near a front side of the rack 10. A plurality of bridge-shaped mounting portions 162 is formed on the pole 16, arranged from top to bottom. Each mounting portion 162 and the pole 16 bound a through hole 163. An opening 121 is defined in the bottom plate 12, near a front end of the bottom plate 12. The opening 121 includes a first opening 122 and a second opening 123 communicating with an end of the first opening 122 adjacent to the side plate 13. The width of the first opening 122 is greater than that of the second opening 123 along a fore-and-aft direction.

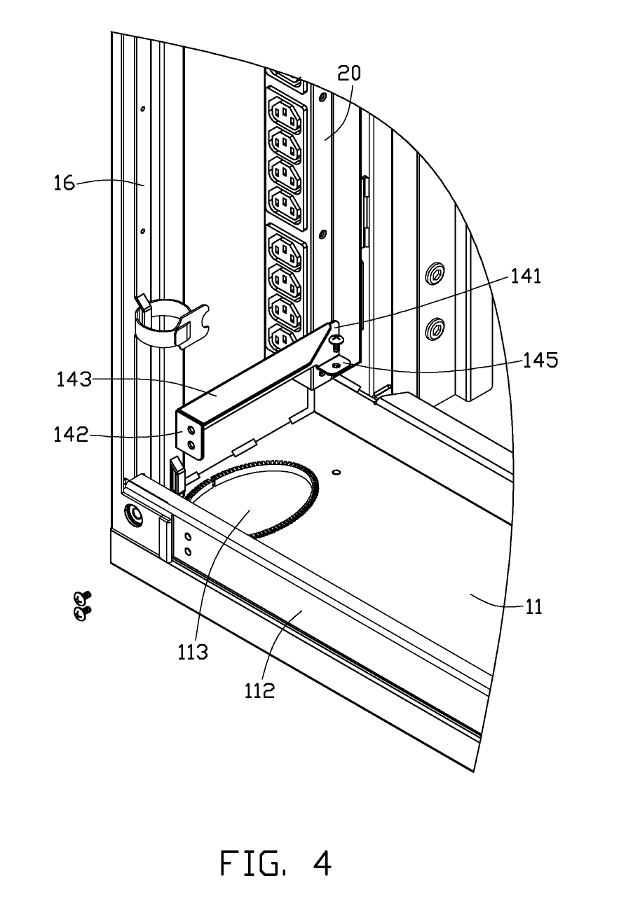

FIG. 4 shows the limitation member 14 including a limitation plate 141, a fastening plate 142 perpendicularly extending from a front end of the limitation plate 141, a connection plate 143 perpendicularly extending from a bottom side of the limitation plate 141 and connected to the fastening plate 142, and a fastening tab 145 perpendicularly extending from a rear end of a top side of the limitation plate 141.

The stop member 15 includes a base plate 151 and a stop plate 152 perpendicularly extending up from a rear side of the base plate 151.

The PDUs 20 are mounted on the inner side of the side plate 13, near a rear side of the pole 16. Each PDU 20 includes a power cable 21. A plug 22 is formed on a distal end of the power cable 21. In the embodiment, the upper PDU 20 illustrates a situation where the power cable 21 of the PDU 20 extends through the top plate 11. The lower PDU 20 illustrates a situation where the power cable 21 of the PDU 20 extends through the bottom plate 12.

A plurality of cable ties 40 respectively extends through the through holes 163, and the power cables 21 are positioned near the pole 16 by means of the cable ties 40.

When the power cable 21 of the PDU 20 is to extend out of the rack 10 through the top plate 11, the plug 22 with the power cable 21 extends through the through hole 113. The fastening plate 142 is fastened on an inner side of the extension plate 112, and the fastening tab 145 is fastened on an inner side of the top plate 11. The limitation plate 141 is located below and bestrides the through hole 113, and the power cable 21 is restrained between the limitation plate 141 and a sidewall bounding the through hole 113, to avoid excessive movement by the power cable 21 in the large area of the through hole 113. After the plug 22 with the power cable 21 has been extended through the top plate 11, the plug 22 is connected to a power socket above the server cabinet, to obtain power for the PDU 20.

When the power cable 21 of the PDU 20 is to extend out of the rack 10 through the bottom plate 12, the plug 22 with the power cable 21 extends through the second opening 123. The base plate 151 is fastened on a top surface of the bottom plate 12, and opposite ends of the base plate 151 are located at opposite sides of the second opening 123. The power cable 21 is restrained between the stop plate 152 and a sidewall bounding the second opening 123 adjacent to the side plate 13, to avoid excessive movement of the power cable 21 in the opening 121. After the plug 22 with the power cable 21 has been extended through the bottom plate 12, the plug 22 is connected to a power socket below the first opening 122, to obtain power for the PDU 20.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a rack comprising a top plate, a bottom plate, and a side plate connected between the top plate and the bottom plate, the top plate defining a first through hole near a front end of the top plate, the bottom plate defining an opening near a front end of the bottom plate; and
a power distribution unit (PDU) fastened on an inner side of the side plate and near a front side of the rack, a power cable of the PDU operable to be extended out of the rack through the first through hole or the opening.

2. The server cabinet of claim 1, wherein the rack further comprises a limitation member below and bestriding the first through hole, the power cable is located between the limitation member and a sidewall bounding the first through hole.

3. The server cabinet of claim 2, wherein an extension plate extends down from a front end of the top plate, the limitation member comprises a limitation plate bestriding and below the first through hole, a fastening plate extending from a front end of the limitation plate and fastened on an inner side of the extension plate, and a fastening tab extending from a rear end of a top side of the limitation plate and fastened on an inner side of the top plate, the power cable is located between the limitation plate and the sidewall bounding the first through hole.

4. The server cabinet of claim 3, wherein the limitation member further comprises a connection plate extending from a bottom side of the limitation plate and connected to the fastening plate.

5. The server cabinet of claim 1, wherein the opening comprises a first opening, a stop member is fastened on a top surface of the bottom plate, opposite ends of the stop member are located at opposite sides of the first opening, the power cable is located between the stop member and a sidewall bounding the first opening adjacent to the side plate.

6. The server cabinet of claim 5, wherein the stop member comprises a base plate fastened on the top surface of the bottom plate, and a stop plate extending up from a side of the base plate adjacent to the side plate.

7. The server cabinet of claim 5, wherein the opening further comprises a second opening communicating with an end of the first opening away from the side plate, the first opening is less than the second opening in width in a fore-and-aft direction.

8. The server cabinet of claim 1, wherein a pole is mounted to the inner side of the side plate, in front of the PDU, a plurality of cable ties is attached to the pole and positions the power cable near the pole.

9. The server cabinet of claim 8, wherein a plurality of bridge-shaped mounting portions is formed on the pole, from top to bottom, each mounting portion and the pole bound a second through hole for a corresponding one of the cable ties to extend through.
